(19) United States
(12) Patent Application Publication
(10) Pub. No.: US 2024/0404422 A1
(43) Pub. Date: Dec. 5, 2024

(54) VEHICLE DEVELOPMENT SUPPORT SYSTEM

(71) Applicant: SUBARU CORPORATION, Tokyo (JP)

(72) Inventors: Yutaka HIWATASHI, Tokyo (JP); Yuji TANIZAKI, Tokyo (JP); Atsushi UDAGAWA, Tokyo (JP); Tsunehiro WATANABE, Tokyo (JP); Satoshi NARUSE, Tokyo (JP)

(21) Appl. No.: 17/925,108

(22) PCT Filed: Jun. 7, 2021
(86) PCT No.: PCT/JP2021/021651

§ 371 Date: Nov. 14, 2022

(51) Int. Cl. G09B 9/04; G06F 3/01

(52) U.S. Cl. CPC G09B 9/04; G06F 3/011; G06F 3/017

(57) ABSTRACT

A vehicle development support system includes a visualization apparatus that generates a video including an operation apparatus in a vehicle; a virtual operation apparatus that displays the video and outputs an operation signal corresponding to a pseudo operation input by an operator on the displayed video; an ECU that outputs a control signal for controlling an in-vehicle device in response to the operation signal; a real-time simulator that simulates a motion of the in-vehicle device in response to the control signal and outputs a simulation result to the visualization apparatus and the ECU; and a synchronization apparatus that synchronizes communication in which the simulation result in the real-time simulator is input into the ECU with communication in which the control signal is input into the real-time simulator. The visualization apparatus updates the video including the operation apparatus in accordance with the simulation result in the real-time simulator.

### TECHNICAL FIELD

The invention relates to a vehicle development support system that supports development of vehicles.

### BACKGROUND ART

A vehicle planning support system has hitherto been known, which displays a vehicle model (an appearance model or an interior model) on a screen to evaluate the vehicle model through running simulation in a virtual space (refer to PTL 1).

### CITATION LIST

### Patent Literature

PTL 1: Japanese Patent No. 4666209

### SUMMARY OF INVENTION

### Technical Problem

Since the operational feeling of an operator with operation apparatuses provided in a vehicle is varied depending on the arrangement state and the type of the operation apparatuses, the sensory evaluation is performed in vehicle development. However, it takes time and cost to manufacture various real machines to perform the sensory evaluation of the various real machines during a planning stage or a design stage of the development.

In order to resolve the above problem, in the related art described above, the evaluation cost and time are to be reduced by visualizing the virtual space and the vehicle model and providing the visualized virtual space and vehicle model to an evaluator. However, the arrangement and the sizes of the operation apparatuses, such as a steering mechanism and a pedal, are visually evaluated with a video and it is not possible to physically experience and evaluate the operational feeling with the operation apparatuses. In addition, although the running simulation is performed in the related art described above, the related art does not support simulation of the motion of an in-vehicle device and a vehicle behavior, which are associated with an operation input with the operation apparatus. Accordingly, it is difficult to appropriately evaluate the operation of the operation apparatus and the motion of the in-vehicle device associated with the operation of the operation apparatus. Consequently, it is difficult to evaluate the operational feeling of the operator with the operation apparatus corresponding to the real machine along with the motion of the in-vehicle device associated with the operation with the operation apparatus in the related art described above.

In order to resolve the above problems in the related art, it is an object of the invention to provide a vehicle development support system capable of evaluating the operational feeling of an operator with an operation apparatus along with the motion of an in-vehicle device associated with the operation without manufacturing a real machine.

### Solution to Problem

In order to resolve the above problems, a vehicle development support system according to an embodiment of the invention includes a visualization apparatus configured to generate a video including an operation apparatus mounted in a vehicle; a virtual operation apparatus configured to display the video including the operation apparatus and generated by the visualization apparatus, and to output an operation signal corresponding to a pseudo operation input by an operator on the displayed video of the operation apparatus; an electronic control unit configured to output a control signal for controlling an in-vehicle device in response to the operation signal; a real-time simulator configured to simulate a motion of the in-vehicle device in response to the control signal and to output a simulation result to the visualization apparatus and the electronic control unit; and a synchronization apparatus configured to synchronize communication in which the simulation result in the real-time simulator is input into the electronic control unit with communication in which the control signal is input into the real-time simulator. The visualization apparatus updates the video including the operation apparatus in accordance with the simulation result in the real-time simulator.

### Advantageous Effects of Invention

With the vehicle development support system according to an embodiment of the invention, it is possible to evaluate the operational feeling of the operator with the operation apparatus along with the motion of the in-vehicle device associated with the operation without manufacturing a real machine.

### BRIEF DESCRIPTION OF DRAWINGS

FIG. 1 is an explanatory diagram illustrating a system configuration of a vehicle development support system according to an embodiment of the invention.

FIG. 2 is a block diagram illustrating a flow of signals in the vehicle development support system.

FIG. 3 is a block diagram illustrating a flow of signals in the vehicle development support system.

FIG. 4 is a sequence diagram illustrating signal processing in one control cycle in the respective components in the vehicle development support system.

FIG. 5 is a block diagram illustrating an exemplary configuration of a virtual operation apparatus in the vehicle development support system.

FIG. 6 is an explanatory diagram illustrating an example of a pseudo operation input in a virtual space of the virtual operation apparatus.

FIG. 7 is an explanatory diagram illustrating another example of the pseudo operation input in the virtual space of the virtual operation apparatus.

FIG. 8 is an explanatory diagram illustrating the positional relationship between the virtual space of the virtual operation apparatus and actual operation apparatuses.

### DESCRIPTION OF EMBODIMENTS

Embodiments of the invention will herein be described with reference to the drawings. The same reference characters in different drawings represent components having the same functions in the following description and a duplicated description of such components is appropriately omitted herein.

A vehicle development support system 1 according to an embodiment of the invention includes a visualization apparatus 30 that generates a video including an operation apparatus mounted in a vehicle; a virtual operation apparatus 10 that displays the video including the operation apparatus, which is generated by the visualization apparatus 30, and that outputs an operation signal corresponding to a pseudo operation input by an operator on the displayed video of the operation apparatus; an ECU 2 that outputs a control signal for controlling an in-vehicle device in response to the operation signal; a real-time simulator 20 that simulates a motion of the in-vehicle device in response to the control signal and that outputs a simulation result to the visualization 30 and the ECU 2; and apparatus a synchronization apparatus 4 that synchronizes communication in which the simulation result in the real-time simulator 20 is input into the ECU 2 with communication in which the control signal is input into the real-time simulator 20. The visualization apparatus 30 updates the video including the operation apparatus in accordance with the simulation result in the real-time simulator 20.

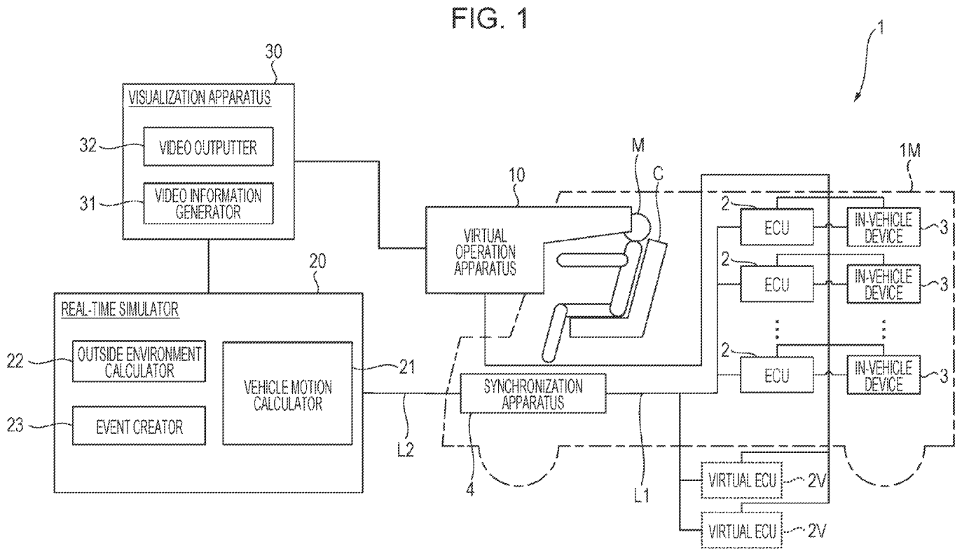

As illustrated in FIG. 1, the vehicle development support system 1 according to the embodiment of the invention builds a system of a closed loop with an intervening operator (person) M who sits in a cockpit C. In the vehicle development support system 1, the cockpit C in which the operator M sits is placed in a frame body 1M.

The vehicle development support system 1 includes the electronic control units (ECUs) 2 mounted in a vehicle and in-vehicle devices 3 controlled by the corresponding ECUs 2. Although an example is illustrated in FIG. 1 in which the vehicle development support system 1 includes the multiple ECUs 2 and the multiple in-vehicle devices 3, the vehicle development support system 1 may include the single ECU 2 and the single in-vehicle device 3 with an evaluation target being specified. The ECU 2 and the in-vehicle device 3 selected from the multiple ECUs 2 and the multiple in-vehicle devices 3 or all the multiple ECUs 2 and all the multiple in-vehicle devices 3 are used as the evaluation targets. The multiple ECUs 2 in the development support system 1 are connected to each other so as to be capable of communication via a communication line L1 in an in-vehicle network (for example, a controller area network (CAN)), as in an actual vehicle.

The vehicle development support system 1 includes the virtual operation apparatus 10. The virtual operation apparatus 10 matches the position coordinate of operation apparatuses for the in-vehicle devices 3 placed in the frame body 1M with the coordinate system of a virtual space to enable the operator M to perform pseudo operation of operation apparatuses in the virtual space while actually touching the operation apparatuses placed in the frame body 1.

The virtual operation apparatus 10 displays videos of the operation apparatuses mounted in the vehicle in the virtual space to cause the operator M to visually recognize the videos and outputs an operation signal in response to a pseudo operation input with the operation apparatus in the virtual space, which is matched with an operation with the actual operation apparatus. The operation signal that is output is transmitted to the ECUs 2 and the in-vehicle devices 3 described above. The virtual operation apparatus 10 places operation mechanisms (a steering operation mechanism, an accelerator operation mechanism, a brake operation mechanism, a shift operation mechanism, and switches for operating the in-vehicle devices 3) of the vehicle in the virtual space in association with the operation apparatuses placed in the frame body 1M. Here, it is sufficient for the operation apparatuses placed in the frame body 1M to simulate the shapes or the likes of the operation apparatuses to be mounted and it is more desirable for the operation apparatuses placed in the frame body 1M to simulate the texture or the like of the operation apparatuses to be mounted.

The vehicle development support system 1 includes a single virtual ECU 2V or multiple virtual ECUs 2V depending on the usage. The virtual ECU 2V simulates a computerized behavior (computerized control function) of an actual ECU when the actual ECU is mounted in the vehicle, instead of the actual ECU mounted in the actual vehicle, and is capable of being composed of a general-purpose controller, such as rapid control prototyping (RCP), or a personal computer (PC). Composing, for example, an ECU that is being developed of the virtual ECU 2V enables cooperation of the ECUs in the entire vehicle to be evaluated even during development. The virtual ECU 2V is one mode of the ECU 2. The ECU 2 described below includes the virtual ECU 2V unless the ECU 2 is discriminated from the actual ECU.

The vehicle development support system 1 includes the real-time simulator 20. The real-time simulator 20 may be composed of a computer including multiple processors and a memory in which programs executed by the processors are stored. The real-time simulator 20 calculates a physical state quantity for operating the in-vehicle device 3 in response to a control signal output from the ECU 2 (the actual ECU) or the virtual ECU 2V to simulate the motion of the in-vehicle device 3 and to simulate a vehicle behavior in association with the motion of the in-vehicle device 3.

The real-time simulator 20 includes, as its software configuration, a vehicle motion calculator (a vehicle motion calculation model) 21 that calculates the physical state quantities of the in-vehicle device to be controlled and the vehicle to output a simulation result, an outside environment calculator (an outside environment calculation model) 22 that calculates outside environment having an influence on the vehicle behavior to reflect the calculated outside environment in the simulation result, and an event creator (an event creation model) 23 that creates an event for the outside environment to reflect the created event in the simulation result.

The vehicle development support system 1 includes the visualization apparatus 30. The visualization apparatus 30 is composed of a computer that performs arithmetic processing of video information. The visualization apparatus 30 transmits a video inside the vehicle, which includes videos of the operation apparatuses mounted in the actual vehicle, to the virtual operation apparatus 10 described above. The visualization apparatus 30 updates the video in accordance with the simulation result in the real-time simulator 20 to transmit the updated video to the virtual operation apparatus 10.

The visualization apparatus 30 generates the video information in accordance with the simulation result in the real-time simulator 20 and causes the operator M to visually recognize the generated video information via the virtual operation apparatus 10. The visualization apparatus 30 includes a video information generator 31, which is a program to operate a processor in the visualization apparatus 30 to generate the video information, and a video outputter 32, which is a program to operate the processor in the visualization apparatus 30 to output the generated video information.

The vehicle development support system 1 includes the synchronization apparatus 4 that synchronizes communication in which the simulation result in the real-time simulator 20 is input into the ECU 2 with communication in which the control signal from the ECU 2 is input into the real-time simulator 20.

The synchronization apparatus 4 is an interface that performs synchronous connection of the communication line L1 at the ECU 2 side and a communication line L2 at the real-time simulator 20 side. The process in which the ECU 2 transmits the control signal is capable of being synchronized with the process in which the real-time simulator 20 transmits the simulation result via the synchronization apparatus 4. One ECU 2 and another ECU 2 in the vehicle development support system 1 are connected to each other so as to be capable of communication via the communication line L1 in the in-vehicle network (for example, the CAN) to realize synchronous communication.

Part of the in-vehicle devices 3 to be mounted in the vehicle is disposed in the frame body IM in the vehicle development support system 1. The in-vehicle devices 3 disposed in the frame body 1M include various sensors and actuators actuating the devices.

In the vehicle development support system 1, for example, the in-vehicle devices in a power train system may be removed from the frame body 1M. However, the vehicle development support system 1 is capable of disposing the ECUs controlling all the in-vehicle devices to be mounted in the actual vehicle, including the in-vehicle devices removed from the frame body 1M, as the ECUs 2 (the actual ECUs) and the virtual ECUs 2V.

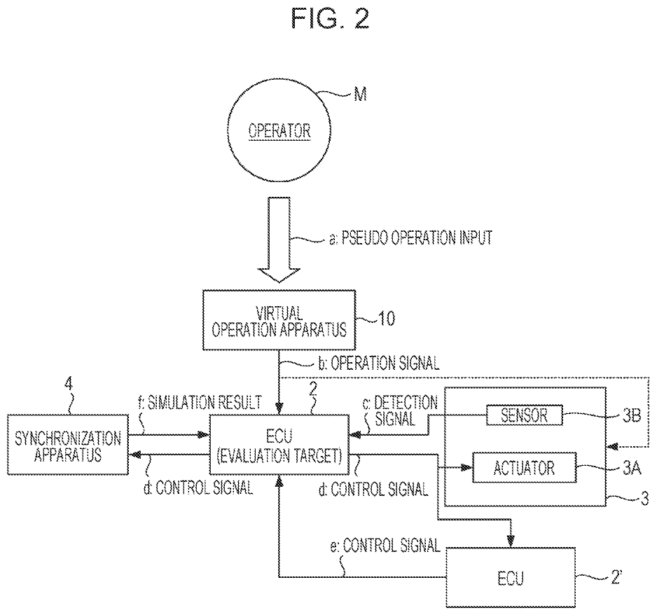

A flow of signals in the vehicle development support system 1 will now be described. FIG. 2 illustrates a case in which the in-vehicle device 3 controlled by the ECU 2, which is the evaluation target, is disposed in the frame body 1M. The in-vehicle device 3 includes an actuator 3A that actuates the device and a sensor 3B that detects the motion of the actuator 3A.

Referring to FIG. 2, when the operator M performs a pseudo operation input a with the virtual operation apparatus 10, the virtual operation apparatus 10 inputs an operation signal b into the ECU 2, which is the evaluation target. Depending on the type of the in-vehicle device 3, the operation signal b is input into the in-vehicle device 3, the actuator 3A works in response to the input operation signal b, and a detection signal c by the sensor 3B, which has detected the motion of the actuator 3A, is input into the ECU 2 as an input signal.

The ECU 2 performs arithmetic processing corresponding to the input signal and outputs a control signal d. A closed loop is formed between the ECU 2 and the in-vehicle device 3, in which the actuator 3A works in response to input of the control signal d, the sensor 3B detects the motion of the actuator 3A to transmit the detection signal c to the ECU 2, and the ECU 2 outputs the control signal d based on the detection signal c.

A closed loop is formed between the ECU 2 and another ECU 2′, in which the ECU 2 outputs the control signal d to the other ECU 2′, the other ECU 2′ performs the arithmetic processing corresponding to the control signal d to transmit a control signal e to the ECU 2, and the ECU 2 transmits the control signal d based on the control signal e to the ECU 2′.

Between the ECU 2 and the real-time simulator 20, the control signal d is transmitted to the real-time simulator 20 via the synchronization apparatus 4, the arithmetic processing (for example, a vehicle motion calculation process) corresponding to the control signal d is performed in the real-time simulator 20, and the physical state quantity, which is a simulation result f and on which the motions of the in-vehicle device 3 and the vehicle are based, is transmitted to the ECU 2 via the synchronization apparatus 4.

Here, the control signal d from the ECU 2, which is the evaluation target, is subjected to the arithmetic processing in accordance with the operation signal b, the detection signal c, the control signal e, and the simulation result f and is output. The operation with the virtual operation apparatus 10, the motion of the ECU 2, the motion of the in-vehicle device 3, and the motion of the other ECU 2′ are reflected in the simulation result f in the real-time simulator 20.

The other ECU 2′ is capable of being composed as the ECU 2 into which another operation signal b is input. In this case, the simulation result f in the real-time simulator 20 is transmitted also to the other ECU 2′, as in the ECU 2, and the control signal e is transmitted from the other ECU 2′ to the real-time simulator 20.

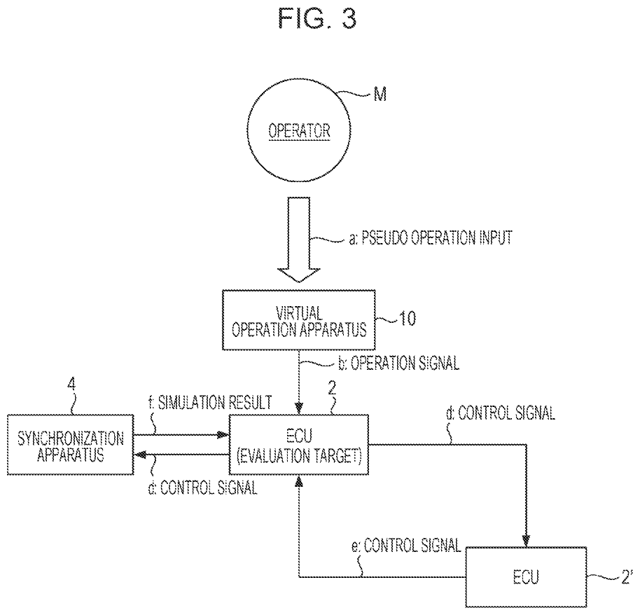

FIG. 3 illustrates a case in which the in-vehicle device 3 controlled by the ECU 2, which is the evaluation target, is not disposed in the frame body 1M. In this case, upon input of the operation signal b associated with the pseudo operation input a by the operator M from the virtual operation apparatus 10 into the ECU 2, which is the evaluation target, the ECU 2 outputs the control signal d. The control signal d is transmitted to the other ECU 2′ and is transmitted to the real-time simulator 20 via the synchronization apparatus 4. The closed loop is formed between the ECU 2 and the other ECU 2′, in which the control signal e is returned in response to transmission of the control signal d, as described above, and the closed loop is formed between the ECU 2 and the real-time simulator 20, in which the simulation result f is returned in response to transmission of the control signal d, as described above. Here, the other ECU 2′ may be configured so as to receive the operation signal b and the simulation result f, as described above.

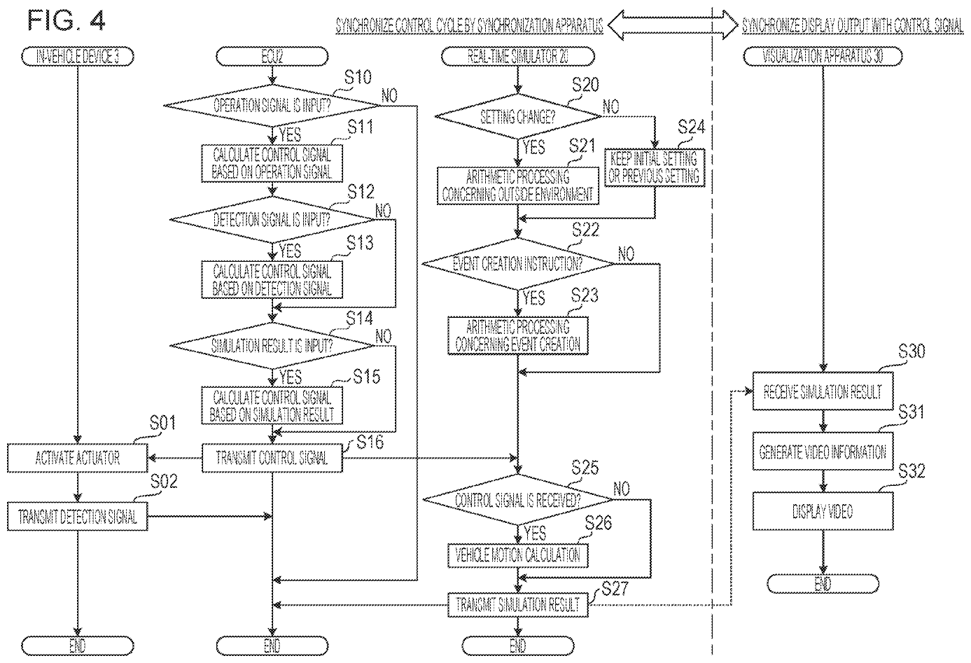

FIG. 4 illustrates signal processing in one control cycle in the respective components in the vehicle development support system 1. Here, since the ECU 2 is connected to the real-time simulator 20 through communication via the synchronization apparatus 4, the processing in each control cycle in the ECU 2 is synchronized with that in the real-time simulator 20. In other words, the ECU 2 is capable of synchronously transmitting and receiving the signal to and from the real-time simulator 20, as in the other ECU connected to the ECU 2 via the in-vehicle network (for example, the CAN).

The ECU 2 determines whether the operation signal b is input in the previous control cycle in each control cycle (Step S10). If the operation signal b is not input in the previous control cycle, the subsequent steps are skipped and the current control cycle is terminated.

The ECU 2 determines whether the detection signal c is input from the sensor 3B in the previous control cycle (Step S12). If the detection signal c is input, the ECU 2 calculates the control signal d based on the detection signal c (Step S13). If the detection signal c is not input, Step S13 is skipped.

The ECU 2 determines whether the simulation result f is input from the real-time simulator 20 in the previous control cycle (Step S14). If the simulation result f is input, the ECU 2 calculates the control signal d based on the simulation result f (Step S15). If the simulation result f is not input, Step S15 is skipped.

Upon calculation of the control signal d in one control cycle, the ECU 2 transmits the calculated control signal d to the in-vehicle device 3 and the real-time simulator 20. Then, the processing in one control cycle is terminated.

Upon reception of the control signal d transmitted from the ECU 2, the in-vehicle device 3 activates the actuator 3A in response to the control signal d (Step S01). The in-vehicle device 3 detects the working state of the actuator 3A with the sensor 3B to transmit the detection signal c to the ECU 2 (Step S02).

The real-time simulator 20 determines whether any setting change is made (Step S20) in the control cycle synchronized with the processing in the ECU 2 described above. If any setting change is made, the real-time simulator 20 performs arithmetic processing concerning the outside environment with the outside environment calculator 22 (Step S21). If no setting change is made, the real-time simulator 20 keeps an initial setting or the previous setting (Step S24).

The real-time simulator 20 determines whether an event creation instruction is issued (Step S22). If the event creation instruction is issued, the real-time simulator 20 performs arithmetic processing concerning event creation (Step S23). If the event creation instruction is not issued, Step S23 is skipped.

The real-time simulator 20 determines whether the control signal d is received (Step S25). If the control signal d is received, the real-time simulator 20 performs vehicle motion calculation corresponding to the control signal d (Step S26). If the control signal d is not received, Step S26 is skipped. The real-time simulator 20 transmits the simulation result f calculated in one control cycle to the ECU 2 (Step S27). Then, the current control cycle is terminated.

As described above, the ECU 2 and the real-time simulator 20 performs the processing in the synchronized control cycles. In contrast, the visualization apparatus 30 may not perform the processing synchronized with the respective control cycles of the ECU 2 and the real-time simulator 20. The visualization apparatus 30 synchronizes the control signal d, which is output from the ECU 2 with the simulation result f being reflected in the control signal d, with video output in the visualization apparatus 30 at certain timing at which the operator has a sense of realism for the input timing of the pseudo operation input a.

In one example, the visualization apparatus 30 receives the simulation result f transmitted from the real-time simulator 20 (Step S30). The visualization apparatus 30 generates the video information with the video information generator 31 (Step S31). The visualization apparatus 30 outputs a video signal to the virtual operation apparatus 10 with the video outputter 32 (Step S32). At this time, the video output (Step S32) is performed each time the control cycle of the ECU 2 or the real-time simulator 20 is performed multiple times to enable synchronization of the video output in the visualization apparatus 30 with the output timing of the control signal d.

With the vehicle development support system 1 having the above configuration, the connection of the ECU 2 to the real-time simulator 20 via the synchronization apparatus 4 causes the real-time simulator 20 to be in a state in which the sensor and the ECU connected to the in-vehicle network are simulated. Information output from the sensor and the ECU, which is not generated unless the vehicle is actually driven, is capable of being generated using the simulation result f in the real-time simulator 20 and the output information is capable of being uploaded on the in-vehicle network. Accordingly, it is possible to operate the ECU 2 and the in-vehicle device 3 in response to an operation with the virtual operation apparatus 10 while simulating a status in which the vehicle is being actually running, to reflect the working states of the ECU 2 and the in-vehicle device 3 in the video in real time and to evaluate the working performances of the ECU 2 and the in-vehicle device 3 while watching the video.

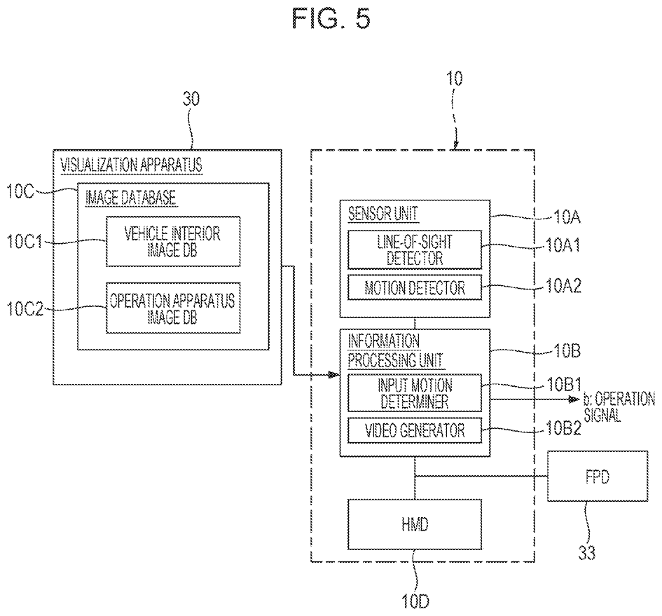

FIG. 5 illustrates an example of the configurations of the virtual operation apparatus 10 and the visualization apparatus 30. The virtual operation apparatus 10 includes a sensor unit 10A composed of various sensors, an information processing unit 10B composed of a single processor or multiple processors, a head mount display (HMD) 10D, and the operation apparatuses (including operation units for the in-vehicle devices 3 and so on) actually touched and operated by the operator M. The operation apparatuses actually operated by the operator M may generate a signal or no signal.

The sensor unit 10A includes a line-of-sight sensor (a line-of-sight detector 10A1) that detects a line of sight of the operator M, an input motion sensor (a motion detector 10A2) that detects the motion of a hand or the like of the operator M, and so on. The sensor unit 10A transmits information about the orientation of the line of sight of the operator M and the motion of a hand or the like of the operator M to the information processing unit 10B. The sensor unit 10A may be permanently affixed to the head mount display 10D.

The information processing unit 10B includes an input motion determiner 10B1 and a video generator 10B2 as programs to perform arithmetic processing of the information transmitted from the sensor unit 10A. The information processing unit 10B generates a video corresponding to the direction to which the line of sight of the operator M is directed and combines an input image associated with the motion of a hand or the like with the video to perform input motion determination to output the operation signal b based on the motion. Although the example is described in which the operation signal b is output based on the motion in the video, the operation signal b may be output based on the motion of the actual operation apparatus placed in the frame body 1M.

The visualization apparatus 30 includes an image database 10C, in addition to the components described above. The image database 10C accumulates image data used by the information processing unit 10B to generate the video. The visualization apparatus 30 includes a vehicle interior image database 10C1 and an operation apparatus image database 10C2 as the image data. In the vehicle interior image database 10C1, various images of the vehicle interior of a vehicle that is being developed (various vehicle interior images) are capable of being set and varied. In the operation apparatus image database 10C2, various images of the various operation apparatuses mounted in the developing vehicle (various operation apparatus images) are capable of being set and varied. Although the visualization apparatus 30 updates the video in accordance with the simulation result f in the real-time simulator 20, as described above, the visualization apparatus 30 acquires the videos of the operation apparatuses from the image database 10C.

The head mount display 10D is worn by the operator M on his/her head to cause the operator to visually recognize the video generated by the information processing unit 10B and to cause the operator M to visually recognize the virtual space. The operator M wears the head mount display 10D and visually recognizes the video generated by the information processing unit 10B to visually recognize the video of the operation apparatuses provided in the developing vehicle and the video of the vehicle interior of the developing vehicle in the virtual space and to visually recognize the input image simulating the motion of a hand or the like of the operator M, which is detected by the sensor unit 10A (the motion detector).

Since the video in the virtual space displayed on the head mount display 10D is in the same space coordinate as that of the physical operation apparatuses placed around the cockpit C, the feeling of operating the physical operation apparatuses is overlapped with the feeling of pseudo operation of the operation apparatuses displayed in the virtual space. Accordingly, the operator M feels like actually operating the operation apparatuses in the virtual space. Here, the display in the virtual space is desirably stereoscopically viewed with parallax. Since the virtual space is recognized by the operator M as the three-dimensional real space in this case and a sense of reality of the feeling described above is increased, the operator M feels like getting in the actual vehicle for operation.

The output from the visualization apparatus 30 described above, that is, the video of the simulation result f in the real-time simulator 20 is input into the information processing unit 10B in the virtual operation apparatus 10. The video of the simulation result f that is input is combined with the video of the virtual operation apparatus 10 in association with the operation signal b output from the virtual operation apparatus 10 and the video of the simulation result f, which is combined with the video of the virtual operation apparatus 10, is displayed on the head mount display 10D.

The video to be displayed on the head mount display 10D is visually recognized by the operator M. However, displaying the video to be displayed on the head mount display 10D in a display 33, such a flat panel display, enables the video visually recognized by the operator M to be visually recognized by multiple evaluators to share the information for the evaluation.

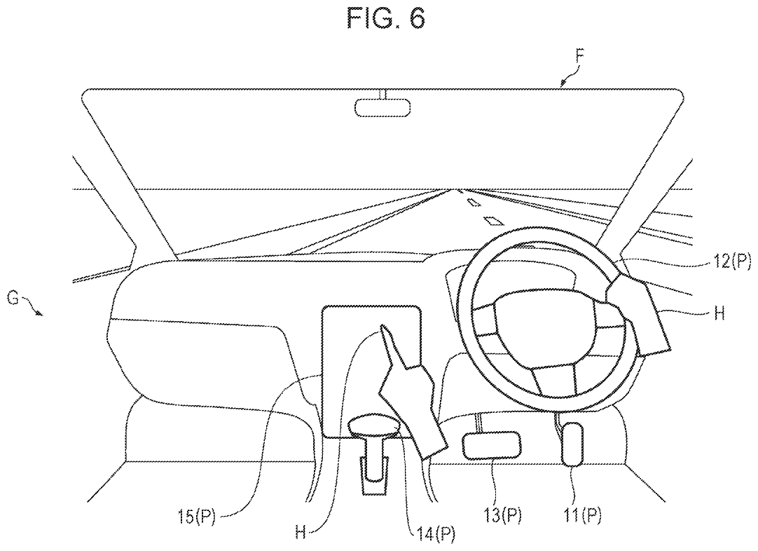

As illustrated in FIG. 6, a video F of the simulation result f described above, a video of a vehicle interior image G, and videos of operation apparatus images P of an accelerator pedal 11, a steering wheel 12, a brake pedal 13, a shift lever 14, a center panel 15, and so on are combined to be displayed in the virtual operation apparatus 10 in the vehicle development support system 1. In addition, an input image H indicating the pseudo operation input a by the operator M is combined with the videos described above to be displayed as a video having a motion matched with the motion of the hand of the pseudo operation input a.

With the virtual operation apparatus 10, in response to the pseudo operation input a by the operator M, the input image H makes a movement simulating the operation corresponding to the pseudo operation input a in the virtual space visually recognized by the operator M and the operation apparatus images P make movements in response to the movement of the input image H to output the operation signal b. As described above, the ECU 2 and the real-time simulator 20 perform the processing in the synchronized control cycles, the video output in the visualization apparatus 30 is synchronized with the control cycle of the real-time simulator 20 to an extent having a sense of realism, and the video output in the visualization apparatus 30 is synchronized with the output of the operation signal b from the virtual operation apparatus 10 at certain timing having a sense of realism.

Accordingly, the operator M has a feeling of operating the operation apparatuses displayed in the virtual space with the pseudo operation input a and is capable of evaluating the operational feeling for the operation apparatuses mounted in the developing vehicle with the pseudo operation in the virtual space. An example of the pseudo operation input a is illustrated in FIG. 6, in which the operator M touches the center panel with his/her first finger of the left hand while operating the steering wheel 12 with his/her right hand.

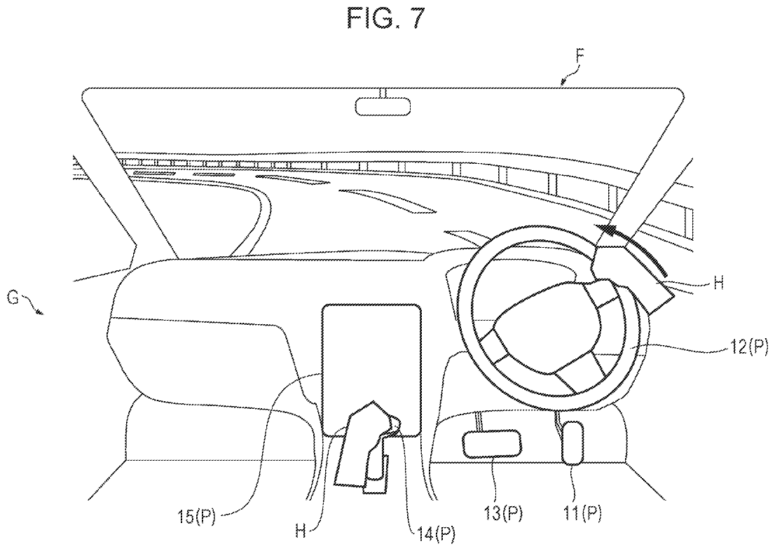

An example is illustrated in FIG. 7, in which the operator M operates the steering wheel 12 and the shift lever 14 with the pseudo operation input a. When a driving operation to drive the vehicle is performed with the pseudo operation input a, the video F of the simulation result f is a video simulating the vehicle behavior corresponding to the operation, as described above. Accordingly, the operator M is capable of physically experiencing the operational feeling for the operation apparatuses that are mounted while physically experiencing the status in which the operator M is driving the vehicle through the visual recognition of the video F.

At this time, since the operation apparatus images P and the vehicle interior image G mounted in the developing vehicle are capable of being appropriately selected from the image database 10C and the operation apparatus images P and the vehicle interior image G that are selected are capable of being displayed in the virtual space, it is possible to concurrently make the settings of the operation apparatuses and the vehicle interior, which influence motion evaluation, at a planning and development stage at which the motion evaluation of the ECUs 2 and the in-vehicle devices 3 is performed. In addition, since the operation apparatus images P and the vehicle interior image G are displayed as the videos corresponding to the direction of the line of sight of the operator M, it is possible to perform the evaluation at the planning and development stage using the videos having an increased sense of presence.

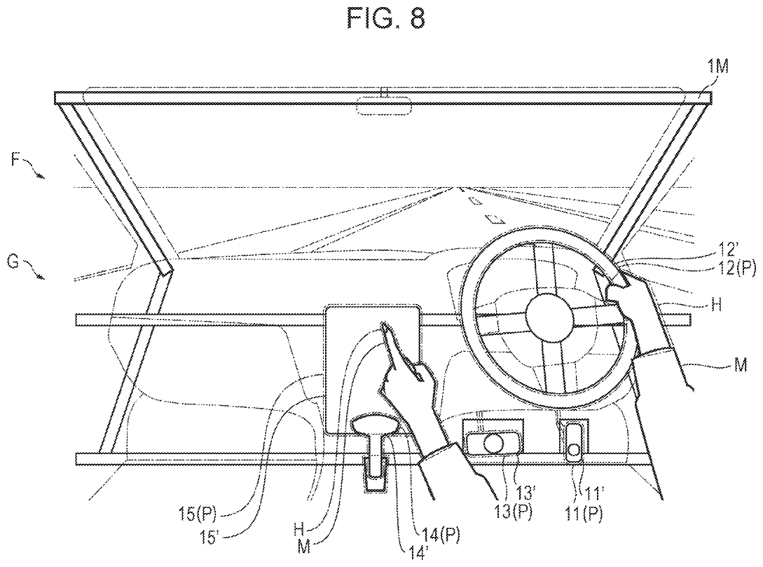

FIG. 8 illustrates the positional relationship between the virtual space of the virtual operation apparatus 10 and the actual operation apparatuses placed in the frame body 1M. As described above, the position coordinate of the virtual space coincides with that of the operation apparatuses including the actual in-vehicle devices 3 placed in the frame body 1M. In the example in FIG. 8, the positions of the videos of the operation apparatus images P of the accelerator pedal 11, the steering wheel 12, the brake pedal 13, the shift lever 14, the center panel 15, and so on, which are displayed in the virtual space, correspond to the positions of models of the operation apparatuses placed in the frame body 1M (an accelerator pedal model 11′, a steering wheel model 12′, a brake pedal model 13′, a shift lever model 14′, and a center panel model 15′).

A wiper, opening and closing of windows, a side mirror, and so on are exemplified as the models generating electrical signals, among the models of the operation apparatuses, in addition to the accelerator pedal model 11′, the steering wheel model 12′, the brake pedal model 13′, and the shift lever model 14′. These models are capable of being created with a three-dimensional printer or the like and may be the models with no motion unless the models are to be subjected to the motion evaluation.

Various electrical switches including the operation switches of an air conditioner are exemplified as the models generating no electrical signal, among the models of the operation apparatus placed in the frame body 1M, in addition to the center panel (touch panel) model 15′. The motion evaluation of the center panel 15 is capable of being performed through transition of the videos in the virtual space.

With the vehicle development support system 1 of the invention described above, it is sufficient to use the models of the operation apparatuses realized in the frame body 1M, the manufacturing time and the manufacturing cost are capable being reduced. Combining the operational feeling of the models with the pseudo operation input with the operation apparatuses in the virtual space, which have the three-dimensional positional relationship coinciding with that of the models, enables the sensory evaluation of human machine interface (HMI) for new operation apparatuses of the developing vehicle to be realized.

As described above, with the vehicle development support system 1 of the invention, it is possible to evaluate the operational feeling of the operation apparatuses mounted in the developing vehicle and a fit of the vehicle interior concurrently with the motion evaluation of the ECUs 2 and the in-vehicle devices 3 at the planning and development stage of vehicle development. Accordingly, it is possible to determine the direction of development and to extract the problems at an early stage during the vehicle development, thus effectively supporting the vehicle development.

Although the embodiments of the invention are described in detail with reference to the drawings, specific configurations are not limited to the embodiments and modifications or the likes in design within the scope of the invention are also included in the invention. The techniques in the above embodiments may be diverted to combine the embodiments unless the objectives, the configurations, and so on are inconsistent to each other or have problems.

### Reference Signs List

1 vehicle development support system
1M frame body
2 ECU
2V virtual ECU
3 in-vehicle device
3A actuator
3B sensor
4 synchronization apparatus
10 virtual operation apparatus
11 accelerator pedal
11′ accelerator pedal model
12 steering wheel
12′ steering wheel model
13 brake pedal
13′ brake pedal model
14 shift lever
14′ shift lever model
15 center panel
15′ center panel model
20 real-time simulator
21 vehicle motion calculator
22 outside environment calculator
23 event creator
30 visualization apparatus
31 video information generator
32 video outputter
33 display
M operator
C cockpit
L1, L2 communication line
P operation apparatus image
F video
G vehicle interior image
H input image

1. A vehicle development support system comprising:
a visualization apparatus configured to generate a video including an operation apparatus mounted in a vehicle;
a virtual operation apparatus configured to display the video including the operation apparatus and generated by the visualization apparatus, and to output an operation signal corresponding to a pseudo operation input by an operator on the displayed video of the operation apparatus;
an electronic control unit configured to output a control signal for controlling an in-vehicle device in response to the operation signal;
a real-time simulator configured to simulate a motion of the in-vehicle device in response to the control signal and to output a simulation result to the visualization apparatus and the electronic control unit; and
a synchronization apparatus configured to synchronize communication in which the simulation result in the real-time simulator is input into the electronic control unit with communication in which the control signal is input into the real-time simulator,
wherein the visualization apparatus updates the video including the operation apparatus in accordance with the simulation result in the real-time simulator.

2. The vehicle development support system according to claim 1,
wherein a position in a virtual space of the operation apparatus displayed in the virtual operation apparatus corresponds to a position of the operation apparatus, which the operator can touch in the pseudo operation input by the operator.

3. The vehicle development support system according to claim 1,
wherein the virtual operation apparatus includes a motion detector that detects a motion of the operator,
wherein the pseudo operation input by the operator is detected with the motion detector, and
wherein the motion detector detects a direction of a line of sight of the operator and displays a vehicle interior image corresponding to the detected direction of the line of sight.

4. The vehicle development support system according to claim 1, further comprising:
a display apparatus configured to cause multiple persons to visually recognize a video of the simulation result, which is combined with the video displayed by the virtual operation apparatus.

5. The vehicle development support system according to claim 1,
wherein the real-time simulator calculates outside environment influencing a vehicle behavior to reflect the calculated outside environment in the simulation result.

6. The vehicle development support system according to claim 5,
wherein the real-time simulator creates an event for the outside environment to reflect the created event in the simulation result.

7. The vehicle development support system according to any of claim 1,
wherein the electronic control unit is disposed in a frame body including a cockpit in which the operator sits.

8. The vehicle development support system according to claim 2,
wherein the virtual operation apparatus includes a motion detector that detects a motion of the operator,
wherein the pseudo operation input by the operator is detected with the motion detector, and
wherein the motion detector detects a direction of a line of sight of the operator and displays a vehicle interior image corresponding to the detected direction of the line of sight.

9. The vehicle development support system according to a claim 2, further comprising:
a display apparatus configured to cause multiple persons to visually recognize a video of the simulation result, which is combined with the video displayed by the virtual operation apparatus.

10. The vehicle development support system according to a claim 3, further comprising:
a display apparatus configured to cause multiple persons to visually recognize a video of the simulation result, which is combined with the video displayed by the virtual operation apparatus.

11. The vehicle development support system according to a claim 8, further comprising:
a display apparatus configured to cause multiple persons to visually recognize a video of the simulation result, which is combined with the video displayed by the virtual operation apparatus.

12. The vehicle development support system according to claim 2,
wherein the real-time simulator calculates outside environment influencing a vehicle behavior to reflect the calculated outside environment in the simulation result.

13. The vehicle development support system according to claim 3,
wherein the real-time simulator calculates outside environment influencing a vehicle behavior to reflect the calculated outside environment in the simulation result.

14. The vehicle development support system according to claim 8,
wherein the real-time simulator calculates outside environment influencing a vehicle behavior to reflect the calculated outside environment in the simulation result.

15. The vehicle development support system according to claim 12,
wherein the real-time simulator creates an event for the outside environment to reflect the created event in the simulation result.

16. The vehicle development support system according to claim 13,
wherein the real-time simulator creates an event for the outside environment to reflect the created event in the simulation result.

17. The vehicle development support system according to claim 14,
wherein the real-time simulator creates an event for the outside environment to reflect the created event in the simulation result.

18. The vehicle development support system according to claim 2,
wherein the electronic control unit is provided in a frame body including a cockpit in which the operator sits.

19. The vehicle development support system according to claim 3,
wherein the electronic control unit is provided in a frame body including a cockpit in which the operator sits.

20. The vehicle development support system according to claim 8,
wherein the electronic control unit is provided in a frame body including a cockpit in which the operator sits.
